(19) United States
(12) Patent Application Publication
(10) Pub. No.: US 2011/0007487 A1
(43) Pub. Date: Jan. 13, 2011

(54) LSI PACKAGE, PRINTED BOARD AND ELECTRONIC DEVICE

(75) Inventor: Satoshi MURAOKA, Yokohama (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/815,399

(22) Filed: Jun. 15, 2010

(30) Foreign Application Priority Data
Jul. 7, 2009 (JP) 2009-160469

(51) Int. Cl. H05K 7/00

(52) U.S. Cl. 361/760

(57) ABSTRACT

A technology capable of reducing a crosstalk noise generated between through holes of an LSI package and a printed board at low cost is provided. In an electronic device in which an LSI package is mounted on a printed board, a plurality of transmission terminals and a plurality of reception terminals are provided, and the plurality of transmission terminals include transmission terminal pairs which transmit a differential signal and the plurality of reception terminals include reception terminal pairs which receive the differential signal. In the LSI package, two transmission terminal pairs and two reception terminal pairs are respectively adjacent to each other and are arranged so that a line which connects the terminals of one pair intersects with a line which connects the terminals of the other pair.

### CROSS-REFERENCE TO RELATED APPLICATION

The present application claims priority from Japanese Patent Application No. 2009-160469 filed on Jul. 7, 2009, the content of which is hereby incorporated by reference into this application.

### TECHNICAL FIELD OF THE INVENTION

The present invention relates to an electronic device in which an LSI package is mounted on a printed board, and more particularly to a technology effectively applied to a through hole arrangement in a low-noise LSI package and printed board.

### BACKGROUND OF THE INVENTION

In recent years, with the increase in the capacity of an electronic device, the signal transmission rate between LSI packages has doubled every three years. In particular, in the backplane for use in a large-capacity data processing device such as a server and a router, the transmission rate faster than 20 Gbps which is the limit of the electrical transmission will be required around the year 2012, and the crosstalk noise between through holes of a printed board that has been neglected so far is increased. This crosstalk noise causes the shortening of the transmission distance and the increase of the bit error rate.

In such a circumstance, for the reduction of the crosstalk noise, the through hole arrangement with the low crosstalk noise is required. For example, Japanese Patent Application Publication No. 2008-525972 (Patent Document 1) discloses an example of arranging through holes in a zigzag pattern as a technology for reducing the crosstalk noise of a connector.

### SUMMARY OF THE INVENTION

Incidentally, FIG. 8 shows the terminal arrangement (through hole arrangement) in the case where the technology of the through hole arrangement in the Patent Document 1 is made to correspond to the LSI package and the printed board of the present invention. In the terminal arrangement of an LSI package 10x (same for printed board) in FIG. 8, with regard to transmission terminal pairs 13p and reception terminal pairs 14p, when the space between each of the terminals is defined as 1 pitch, the transmission terminal pairs 13p and the reception terminal pairs 14p are respectively arranged in a zigzag pattern with a shift of ½ pitch in a vertical direction (referred to as conventional example 1). In FIG. 8, the region with the signal density represented by 8 pairs/24 terminals is shown. However, the technology of the Patent Document 1 is intended for a connector and is not applied to an LSI package and a printed board like the present invention.

Also, the inventor of the present invention studied the terminal arrangement (through hole arrangement) of an LSI package and a printed board shown in FIG. 9 as a technology for reducing the crosstalk noise to be a premise of the present invention. In the terminal arrangement of an LSI package 10y (same for printed board) in FIG. 9, with regard to the transmission terminal pairs 13p and the reception terminal pairs 14p, spaces between the transmission terminal pairs 13p and those between the reception terminal pairs 14p are widened to make the electrical connection between the terminal pairs less densely (referred to as conventional example 2). In the technology of the conventional example 2, however, the signal density has a value represented by 8 pairs/48 terminals, and the signal density is reduced to 50% compared with the conventional example 1, so that the size of the LSI package is increased, which leads to the cost increase.

Therefore, an object of the present invention is to provide a technology capable of reducing the crosstalk noise generated between the through holes of an LSI package and a printed board at low cost.

The above and other objects and novel characteristics of the present invention will be apparent from the description of the present specification and the accompanying drawings.

The typical ones of the inventions disclosed in the present application will be briefly described as follows.

That is, one typical invention is applied to an LSI package and a printed board, and the LSI package and the printed board comprises: a plurality of transmission terminals; and a plurality of reception terminals, and the plurality of transmission terminals include transmission terminal pairs which transmit a differential signal and the plurality of reception terminals include reception terminal pairs which receive the differential signal. In this configuration, two of the transmission terminal pairs and two of the reception terminal pairs are respectively adjacent to each other and are arranged so that a line which connects the terminals of one terminal pair intersects with a line which connects the terminals of the other terminal pair. Alternatively, the transmission terminal pair and the reception terminal pair are arranged apart from each other by a distance equivalent to two terminals or more.

The effects obtained by typical embodiments of the invention disclosed in the present application will be briefly described below.

That is, as the effect obtained by typical embodiments of the invention, the crosstalk noise generated between the through holes of an LSI package and a printed board can be reduced at low cost.

### BRIEF DESCRIPTIONS OF THE DRAWINGS

FIG. 1 is a diagram showing a general structure of the electronic device according to the first embodiment of the present invention;

FIG. 2 is a diagram showing a terminal arrangement of the LSI package according to the first embodiment of the present invention;

FIG. 3 is a diagram showing a terminal arrangement of the printed board according to the first embodiment of the present invention;

FIG. 4A is a diagram showing the action of the magnetic field by the current of the transmission terminal pairs and the reception terminal pairs of the LSI package and the printed board according to the first embodiment of the present invention;

FIG. 4B is a diagram showing the action of the electric field by the current of the transmission terminal pairs and the reception terminal pairs of the LSI package and the printed board according to the first embodiment of the present invention;

FIG. 5 is a diagram showing the effect of reducing the crosstalk noise obtained by simulation according to the first embodiment of the present invention;

FIG. 6 is a diagram showing a terminal arrangement of the LSI package according to the second embodiment of the present invention;

FIG. 7 is a diagram showing a terminal arrangement of the printed board according to the second embodiment of the present invention;

FIG. 8 is a diagram showing a terminal arrangement of an LSI package in the case where the technology of the through hole arrangement in the Patent Document 1 is made to correspond to the LSI package and the printed board of the present invention; and

FIG. 9 is a diagram showing a terminal arrangement of an LSI package studied as a premise of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof will be omitted.

### First Embodiment

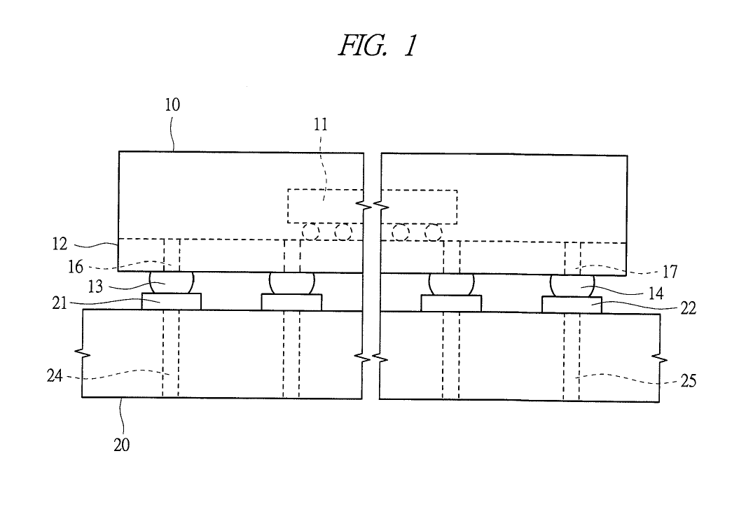

An electronic device and an LSI package and a printed board that makeup the electronic device according to the first embodiment of the present invention will be described with reference to FIG. 1 to FIG. 5.

FIG. 1 is a diagram showing a general structure of the electronic device according to the first embodiment.

The electronic device according to the first embodiment is made up of an LSI package 10, a printed board 20 for mounting the LSI package 10 and others.

The LSI package 10 includes a semiconductor chip 11 in which circuits are formed, an expansion board 12 on which the semiconductor chip 11 is mounted and others. In the LSI package 10, though the details thereof are described later, a plurality of transmission terminals 13, a plurality of reception terminals 14 and others are arranged on a mounting surface, to the printed board 20. The transmission terminals 13 and the reception terminals 14 are connected to through holes 16 and 17 in the expansion board 12. The semiconductor chip 11 is electrically connected to the transmission terminals 13 and the reception terminals 14 via the through holes 16 and 17 and wirings (not shown).

In the printed board 20, though the details thereof are described later, a plurality of transmission terminals 21, a plurality of reception terminals 22 and others are arranged on a mounting surface of the LSI package 10. The transmission terminals 21 and the reception terminals 22 are connected to through holes 24 and 25 in the printed board 20.

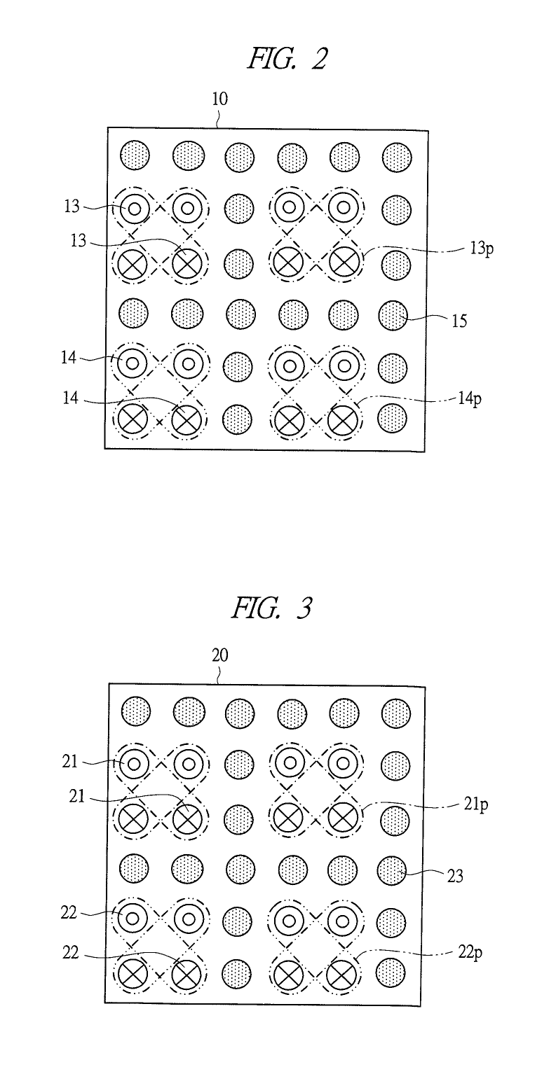

FIG. 2 is a diagram showing a terminal arrangement of the LSI package 10. FIG. 2 is a diagram of the LSI package 10 viewed from a mounting surface side to the printed board 20.

In the LSI package 10, on the mounting surface to the printed board 20, a plurality of transmission terminal pairs 13p which transmit a differential signal are arranged as the plurality of transmission terminals 13 and a plurality of reception terminal pairs 14p which receive the differential signal are arranged as the plurality of reception terminals 14. In this LSI package 10, in particular, two transmission terminal pairs 13p are adjacent to each other and are arranged so that a line which connects the terminals of one transmission terminal pair 13p intersects with a line which connects the terminals of the other transmission terminal pair 13p. Similarly, two reception terminal pairs 14p are adjacent to each other and are arranged so that a line which connects the terminals of one reception terminal pair 14p intersects with a line which connects the terminals of the other reception terminal pair 14p.

FIG. 2 shows the region of 8 terminal pairs by using an example with the signal density represented by 8 pairs/36 terminals. In FIG. 2, four transmission terminal pairs 13p are arranged on an upper side and four reception terminal pairs 14p are arranged on a lower side, and the terminals other than these are GND/power supply (GND or power supply) terminals 15. Since the transmission terminal pairs 13p and the reception terminal pairs 14p are intended for a differential signal, the terminals in which current flows from the back to the front of FIG. 2 are denoted by circle marks, and the terminals in which current flows from the front to the back of FIG. 2 are denoted by x marks.

With regard to the two transmission terminal pairs 13p, these two pairs are adjacent to each other and are arranged so that a line which connects the terminals of one pair intersects with a line which connects the terminals of the other pair (FIG. 2 shows an example in which lines intersect at a right angle). More specifically, a line which connects the terminals of one pair intersects with a line which connects the terminals of the other pair at a right angle.

With regard to the two reception terminal pairs 14p, similarly, these two pairs are adjacent to each other and are arranged so that a line which connects the terminals of one pair intersects with a line which connects the terminals of the other pair (FIG. 2 shows an example in which lines intersect at a right angle).

Through holes of the expansion board 12 connected to each of the transmission terminal pairs 13p, the reception terminal pairs 14p and the GND/power supply terminals 15 of the LSI package 10 are arranged in the same manner as the transmission terminal pairs 13p, the reception terminal pairs 14p and the GND/power supply terminals 15. More specifically, the through holes in the expansion board 12 of the LSI package 10 are also arranged as shown in FIG. 2.

FIG. 3 is a diagram showing a terminal arrangement of the printed board 20. FIG. 3 is a diagram of the printed board 20 viewed from a mounting surface side of the LSI package 10. FIG. 3 shows a region corresponding to FIG. 2, and the region of 8 terminal pairs is shown by using an example with the signal density represented by 8 pairs/36 terminals.

In the printed board 20, similarly to the LSI package 10, on the mounting surface of the LSI package 10, a plurality of transmission terminal pairs 21p which transmit a differential signal are arranged as the plurality of transmission terminals 21 and a plurality of reception terminal pairs 22p which receive the differential signal are arranged as the plurality of reception terminals 22. Also in this printed board 20, similarly to the LSI package 10, in particular, two transmission terminal pairs 21p are adjacent to each other and are arranged so that a line which connects the terminals of one pair intersects with a line which connects the terminals of the other pair, and two reception terminal pairs 22p are adjacent to each other and are arranged so that a line which connects the terminals of one pair intersects with a line which connects the terminals of the other pair (FIG. 3 shows an example in which lines intersect at a right angle). The terminals other than these are GND/power supply (GND or power supply) terminals 23.

Through holes connected to each of the transmission terminal pairs 21p, the reception terminal pairs 22p and the GND/power supply terminals 23 of the printed board 20 are arranged in the same manner as the transmission terminal pairs 21p, the reception terminal pairs 22p and the GND/power supply terminals 23. More specifically, the through holes in the printed board 20 are also arranged as shown in FIG. 3.

In the state where the LSI package 10 is mounted on the printed board 20, the transmission terminal pairs 13p of the LSI package 10 are electrically connected to the transmission terminal pairs 21p of the printed board 20, and similarly, the reception terminal pairs 14p of the LSI package 10 are electrically connected to the reception terminal pairs 22p of the printed board 20. Also, with regard to the GND/power supply terminals, the GND/power supply terminals 15 of the LSI package 10 are electrically connected to the GND/power supply terminals 23 of the printed board 20. By mounting the LSI package 10 on the printed board 20 to electrically connect the LSI package 10 and the printed board 20 in the above-described manner, the electronic device according to the present embodiment is achieved.

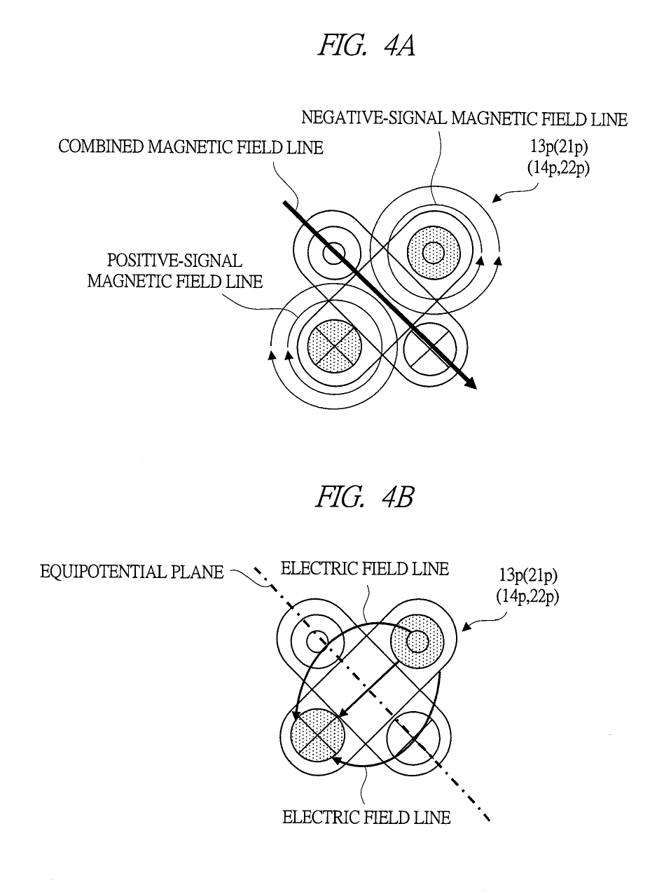

FIG. 4A and FIG. 4B are diagrams showing the actions of the magnetic field and the electric field by the current of the transmission terminal pairs 13p and 21p and the reception terminal pairs 14p and 22p of the LSI package 10 and the printed board 20. Since the current flowing in the transmission terminal pairs 13p and 21p and the reception terminal pairs 14p and 22p corresponds to the current flowing in the through holes connected to each terminal, the description will be made here while focusing on the through holes.

As shown in FIG. 4A, when the two transmission terminal pairs 13p (21p) are considered (same for the two reception terminal pairs 14p and 22p), the two pairs are adjacent to each other and are arranged so that a line which connects the terminals of one pair intersects with a line which connects the terminals of the other pair. When this arrangement is viewed in terms of the magnetic field, by arranging the through holes of one pair so that the magnetic field caused by a positive signal and the magnetic field caused by a negative signal of the through holes of the other pair intersect at a right angle, the coupling of differential mode can be made 0. More specifically, since the electric fields do not interfere with each other on a magnetic field line obtained by combining a positive-signal magnetic field line and a negative-signal magnetic field line, the crosstalk noise generated between the through holes can be reduced.

Further, as shown in FIG. 4B, when this arrangement is viewed in terms of the electric field, by arranging through holes of one pair on an equipotential plane at the positions of equal distance from the two signals of the positive signal and the negative signal of the through holes of the other pair, the coupling of electric fields can be made 0. More specifically, since the common-mode voltage levels of the pairs are cancelled out with each other, the crosstalk noise generated between the through holes can be reduced.

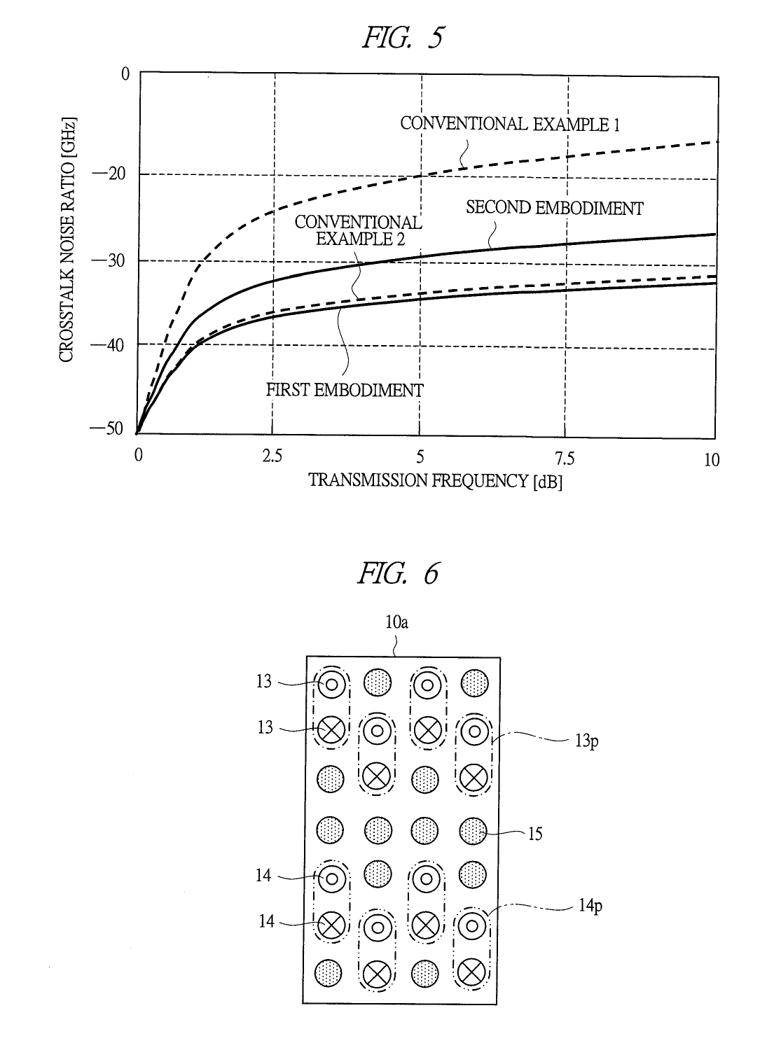

FIG. 5 is a diagram showing the effect of reducing the crosstalk noise obtained by simulation. FIG. 5 shows the crosstalk noise ratio [dB] (vertical axis) with respect to the transmission frequency [GHz] (horizontal axis) of the first embodiment (also the second embodiment described later), the above-described conventional example 1 and conventional example 2.

As is apparent from FIG. 5, according to the first embodiment, when the transmission frequency is 5 GHz (corresponding to the case where the transmission rate is 10 Gbps), the crosstalk noise ratio can be reduced from −20 dB (10% of signal amplitude) to −34 dB (2.0% of signal amplitude), and the effect equivalent to the conventional example 2 can be achieved, and although the signal density is reduced because the terminal arrangement is changed to 8 pairs/36 terminals from 8 pairs/24 terminals of the conventional example 1, the reduction in signal density can be limited to 33%.

As described above, according to the first embodiment, by the terminal arrangement (through hole arrangement) in which the transmission terminal pairs 13p and 21p and the reception terminal pairs 14p and 22p of the LSI package 10 and the printed board 20 are respectively adjacent to each other and are arranged so that a line which connects the terminals of one pair intersects with a line which connects the terminals of the other pair, the crosstalk noise between the through holes can be reduced. As a result, since the reduction in signal density can be minimized and the size increase of the LSI package 10 is unnecessary, the cost increase can be suppressed, so that the reduction in the crosstalk noise generated between the through holes of the LSI package 10 and the printed board 20 can be achieved at low cost.

Note that the terminal arrangement (through hole arrangement) of the transmission terminal pairs 13p and 21p and the reception terminal pairs 14p and 22p according to the first embodiment is not limited to that in which a line which connects the terminals of one pair intersects with a line which connects the terminals of the other pair at a right angle as described above, and for example, the terminal arrangement in which the line which connects the terminals of one pair intersects with the line which connects the terminals of the other pair at an arbitrary angle can also be employed. Further, the terminal arrangement in which the lines of three or more pairs intersect with each other can also be employed.

### Second Embodiment

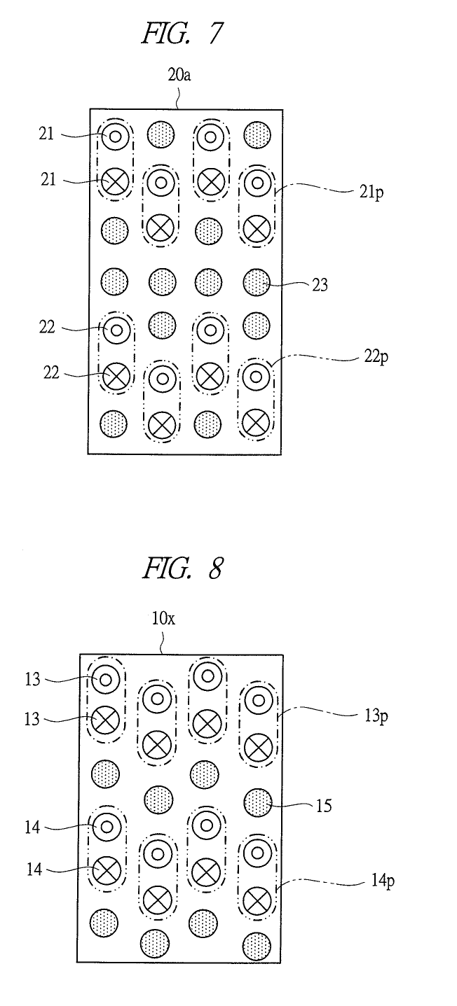

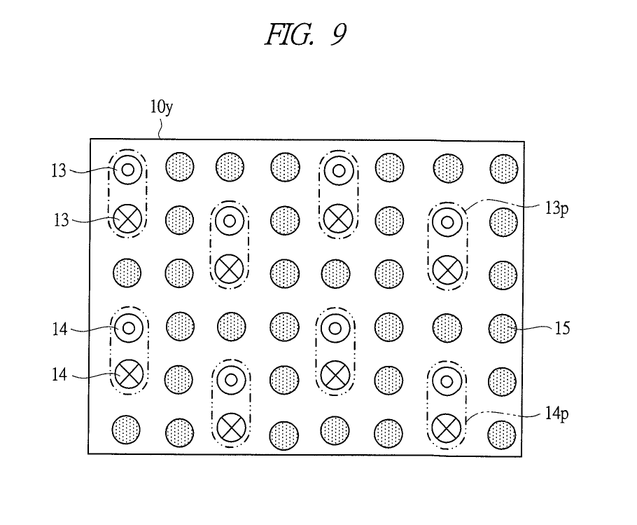

An electronic device and an LSI package and a printed board that make up the electronic device according to the second embodiment of the present invention will be described with reference to FIG. 6 and FIG. 7.

Since the general structure of the electronic device according to the second embodiment is the same as that of the above-described first embodiment shown in FIG. 1, the description thereof is omitted here. The second embodiment is different from the first embodiment in the terminal arrangement (through hole arrangement) of the transmission terminal pairs 13p and 21p and the reception terminal pairs 14p and 22p of an LSI package 10a and a printed board 20a. The difference will be mainly described below.

FIG. 6 is a diagram showing the terminal arrangement of the LSI package 10a. FIG. 6 is a diagram of the LSI package 10a viewed from a mounting surface side to the printed board 20a. Note that the through holes in the expansion board 12 of the LSI package 10a are also arranged as shown in FIG. 6.

In the LSI package 10a, on the mounting surface to the printed board 20a, a plurality of transmission terminal pairs 13p which transmit a differential signal are arranged as the plurality of transmission terminals 13 and a plurality of reception terminal pairs 14p which receive the differential signal are arranged as the plurality of reception terminals 14. In this LSI package 10a, in particular, the transmission terminal pair 13p and the reception terminal pair 14p are arranged apart from each other by a distance equivalent to two terminals or more (FIG. 6 shows an example of a distance equivalent to two terminals).

FIG. 6 shows the region of 8 terminal pairs by using an example with the signal density represented by 8 pairs/28 terminals. In FIG. 6, four transmission terminal pairs 13p are arranged on an upper side and four reception terminal pairs 14p are arranged on a lower side, and the terminals other than these are the GND/power supply terminals 15. Since the transmission terminal pairs 13p and the reception terminal pairs 14p are intended for a differential signal, the terminals in which current flows from the back to the front of FIG. 6 are denoted by circle marks, and the terminals in which current flows from the front to the back of FIG. 6 are denoted by x marks.

The transmission terminal pair 13p and the reception terminal pair 14p are arranged apart from each other by a distance equivalent to two terminals. More specifically, the two GND/power supply terminals 15 are disposed between the transmission terminal pair 13p arranged on an upper side and the reception terminal pair 14p arranged on a lower side.

Furthermore, when the space between each of the terminals is defined as 1 pitch, the adjacent transmission terminal pairs 13p arranged on an upper side are arranged with a shift of 1 pitch in a vertical direction. Similarly, the adjacent reception terminal pairs 14p arranged on a lower side are also arranged with a shift of 1 pitch in a vertical direction.

FIG. 7 is a diagram showing a terminal arrangement of the printed board 20a. FIG. 7 is a diagram of the printed board 20a viewed from a mounting surface side of the LSI package 10a. FIG. 7 shows a region corresponding to FIG. 6, and the region of 8 terminal pairs is shown by using an example with the signal density represented by 8 pairs/28 terminals. Note that the through holes in the printed board 20a are also arranged as shown in FIG. 7.

In the printed board 20a, similarly to the LSI package 10a, on the mounting surface of the LSI package 10a, a plurality of transmission terminal pairs 21p which transmit a differential signal are arranged as the plurality of transmission terminals 21 and a plurality of reception terminal pairs 22p which receive the differential signal are arranged as the plurality of reception terminals 22. Also in this printed board 20a, similarly to the LSI package 10a, in particular, the transmission terminal pair 21p and the reception terminal pair 22p are arranged apart from each other by a distance equivalent to two terminals or more (FIG. 7 shows an example of a distance equivalent to two terminals).

As is apparent from FIG. 5 showing the effect of reducing the crosstalk noise obtained by simulation, although it falls short of the first embodiment, the terminal arrangement according to the second embodiment can reduce the crosstalk noise ratio to −29 dB when the transmission frequency is 5 GHz (corresponding to the case where the transmission rate is 10 Gbps), and although the signal density is reduced because the terminal arrangement is changed to 8 pairs/28 terminals from 8 pairs/24 terminals of the conventional example 1, the reduction in signal density can be limited to 14%.

As described above, according to the second embodiment, by the terminal arrangement (through hole arrangement) in which the transmission terminal pairs 13p and 21p and the reception terminal pairs 14p and 22p of the LSI package 10a and the printed board 20a are arranged apart from each other by the distance equivalent to two terminals or more, the crosstalk noise between the through holes can be reduced. As a result, the reduction in signal density can be minimized and the size increase of the LSI package 10a is unnecessary, the cost increase can be suppressed, so that the reduction in the crosstalk noise generated between the through holes of the LSI package 10a and the printed board 20a can be achieved at low cost.

Note that the terminal arrangement (through hole arrangement) of the transmission terminal pairs 13p and 21p and the reception terminal pairs 14p and 22p according to the second embodiment is not limited to that in which the terminal pairs are arranged apart from each other by the distance equivalent to two terminals, and for example, the terminal arrangement in which the terminal pairs are arranged apart from each other by the distance equivalent to three terminals or more can also be employed. Further, the terminal arrangement in which the adjacent terminal pairs are arranged with a shift of less than 1 pitch in a vertical direction can also be employed.

Also, the terminal arrangement (through hole arrangement) obtained by combining the second embodiment and the first embodiment is also possible. For example, it is possible to apply the terminal arrangement of the second embodiment to the transmission terminal pairs 13p and 21p and apply the terminal arrangement of the first embodiment to the reception terminal pairs 14p and 22p. By applying the terminal arrangement in which a line which connects the terminals of one pair intersects with a line which connects the terminals of the other pair only to the reception terminal pairs 14p and 22p particularly affected by the crosstalk noise in this manner, the differential noise from the common mode can be prevented.

In the foregoing, the invention made by the inventor of the present invention has been concretely described based on the embodiments. However, it is needless to say that the present invention is not limited to the foregoing embodiments and various modifications and alterations can be made within the scope of the present invention.

The present invention relates to an electronic device in which an LSI package is mounted on a printed board and can be used particularly for a technology of a terminal arrangement (through hole arrangement) in a low-noise LSI package and printed board.

1. An LSI package comprising:
a plurality of transmission terminals; and
a plurality of reception terminals,
the plurality of transmission terminals including transmission terminal pairs which transmit a differential signal, and the plurality of reception terminals including reception terminal pairs which receive the differential signal,
wherein the transmission terminal pair and the reception terminal pair are arranged apart from each other by a distance equivalent to two terminals or more.

2. A printed board comprising:
a plurality of transmission terminals; and
a plurality of reception terminals,
the plurality of transmission terminals including transmission terminal pairs which transmit a differential signal, and the plurality of reception terminals including reception terminal pairs which receive the differential signal,
wherein the transmission terminal pair and the reception terminal pair are arranged apart from each other by a distance equivalent to two terminals or more.

3. An electronic device comprising:
an LSI package; and
a printed board for mounting the LSI package,
wherein each of the LSI package and the printed board includes:
a plurality of transmission terminals, and
a plurality of reception terminals,
the plurality of transmission terminals including transmission terminal pairs which transmit a differential signal, and the plurality of reception terminals including reception terminal pairs which receive the differential signal,
the transmission terminal pair and the reception terminal pair being arranged apart from each other by a distance equivalent to two terminals or more.

4. An LSI package comprising:
a plurality of transmission terminals; and
a plurality of reception terminals,
the plurality of transmission terminals including transmission terminal pairs which transmit a differential signal, and the plurality of reception terminals including reception terminal pairs which receive the differential signal,
wherein two of the transmission terminal pairs are adjacent to each other and are arranged so that a line which connects the terminals of one transmission terminal pair intersects with a line which connects the terminals of the other transmission terminal pair, and
two of the reception terminal pairs are adjacent to each other and are arranged so that a line which connects the terminals of one reception terminal pair intersects with a line which connects the terminals of the other reception terminal pair.

5. The LSI package according to claim 1,
wherein two of the transmission terminal pairs are adjacent to each other and are arranged so that a line which connects the terminals of one transmission terminal pair intersects with a line which connects the terminals of the other transmission terminal pair, and
two of the reception terminal pairs are adjacent to each other and are arranged so that a line which connects the terminals of one reception terminal pair intersects with a line which connects the terminals of the other reception terminal pair.

6. The printed board according to claim 2,
wherein two of the transmission terminal pairs are adjacent to each other and are arranged so that a line which connects the terminals of one transmission terminal pair intersects with a line which connects the terminals of the other transmission terminal pair, and
two of the reception terminal pairs are adjacent to each other and are arranged so that a line which connects the terminals of one reception terminal pair intersects with a line which connects the terminals of the other reception terminal pair.

7. An electronic device according to claim 3, wherein in each of the LSI package and the printed board:
two of the transmission terminal pairs are adjacent to each other and are arranged so that a line which connects the terminals of one transmission terminal pair intersects with a line which connects the terminals of the other transmission terminal pair, and
two of the reception terminal pairs are adjacent to each other and are arranged so that a line which connects the terminals of one reception terminal pair intersects with a line which connects the terminals of the other reception terminal pair.
